(19) United States
(12) Patent Application Publication
(10) Pub. No.: US 2020/0195003 A1
(43) Pub. Date: Jun. 18, 2020

(54) ORGANIC SEMICONDUCTOR DEVICE, DRIVING DEVICE AND DRIVING METHOD

(71) Applicant: Industrial Technology Research Institute, Hsinchu (TW)

(72) Inventors: Hsuan-Yu Lin, Changhua County (TW); Cheng-Yen Tsai, Keelung City (TW)

(73) Assignee: Industrial Technology Research Institute, Hsinchu (TW)

(21) Appl. No.: 16/232,038

(22) Filed: Dec. 25, 2018

(30) Foreign Application Priority Data
Dec. 12, 2018 (TW) 107144887

(51) Int. Cl. H02H 7/20; H01L 51/52; H03K 17/0812; H05B 33/08

(52) U.S. Cl. CPC H02H 7/205; H01L 51/5237; H01L 2251/568; H05B 33/0896; H01L 2251/5392; H03K 17/08122

(57) ABSTRACT

An organic semiconductor device, a driving device and a driving method are provided. The driving device is configured to drive a load. The driving device includes a short circuit protection circuit and a delay circuit. The short circuit protection circuit is configured to provide an enable signal. The delay circuit provides a delay time length according to the energy passing through the load, and determines a start time point of the short circuit protection circuit to provide the enable signal according to the delay time length.

### CROSS-REFERENCE TO RELATED APPLICATION

This application claims the priority benefits of Taiwan application serial no. 107144887, filed on Dec. 12, 2018. The entirety of the above-mentioned patent application is hereby incorporated by reference herein and made a part of this specification.

### TECHNICAL FIELD

The present disclosure relates to an organic semiconductor device, a driving device, and a driving method.

### BACKGROUND

Organic semiconductor devices have gained more and more attention because of their light weight and thinness adapted to hardware devices. However, short-circuit easily occurs to partial region of the organic semiconductor device due to uneven energy distribution. Once the short-circuit point is formed, the crowded current at the short-circuit point causes the temperature to rise, which makes the organic layer to deteriorate and the range of coking to expand, and the area of the short-circuit point is enlarged, leading to the failure of the organic semiconductor device. Therefore, it is an important issue for practitioner of the field to find out how to provide a mechanism for dealing with short-circuit suitable for an organic semiconductor device.

### SUMMARY

The present disclosure provides an organic semiconductor device, a driving device, and a driving method having a mechanism for dealing with short-circuit.

The driving device of the present disclosure is configured to drive a load. The driving device includes a short circuit protection circuit and a delay circuit. The short circuit protection circuit is configured to provide an enable signal. The delay circuit provides a delay time length according to the energy passing through the load, and determines a start time point of the short circuit protection circuit to provide the enable signal according to the delay time length.

The organic semiconductor device in the disclosure includes a load and the above-described driving device. The driving device is configured to drive the load.

The driving method of the present disclosure includes: providing a delay time length according to the energy passing through the load; and determining a start time point of providing the enable signal according to the length of the delay time.

Several exemplary embodiments accompanied with figures are described in detail below to further describe the disclosure in details.

### BRIEF DESCRIPTION OF THE DRAWINGS

FIG. 1 is a schematic view of an organic semiconductor device according to a first embodiment of the present disclosure.

FIG. 2A to FIG. 2E schematically illustrate the self-repairing function performed by a heat-shrinkable film in a light-emitting element.

FIG. 3 is a schematic view of an organic semiconductor device according to a second embodiment of the present disclosure.

FIG. 4 is a schematic view of an organic semiconductor device according to a third embodiment of the present disclosure.

FIG. 5 is a schematic view of an organic semiconductor device according to a fourth embodiment of the present disclosure.

FIG. 6 is a schematic view of an organic semiconductor device according to a fifth embodiment of the present disclosure.

FIG. 7 is a schematic view of a delay circuit, a start switch, and a short circuit protection circuit according to a fifth embodiment.

FIG. 8 is a schematic waveform diagram of a power supply, a load voltage, and an enable signal according to the embodiment of FIG. 7.

FIG. 9A is a schematic view of another short circuit protection circuit according to the fifth embodiment of the present disclosure.

FIG. 9B is a schematic view of still another short circuit protection circuit according to the fifth embodiment of the present disclosure.

FIG. 10 is a schematic view of an organic semiconductor device according to the sixth embodiment of the present disclosure.

FIG. 11A is a schematic view of an organic semiconductor device according to a seventh embodiment of the present disclosure.

FIG. 11B is a schematic view of an organic semiconductor device according to an eighth embodiment of the present disclosure.

FIG. 12 is a flow chart of a driving method according to an embodiment of the disclosure.

FIG. 13 is a flow chart of a driving method according to step S120.

FIG. 14 is a flow chart of another driving method according to step S120.

### DESCRIPTION OF EMBODIMENTS

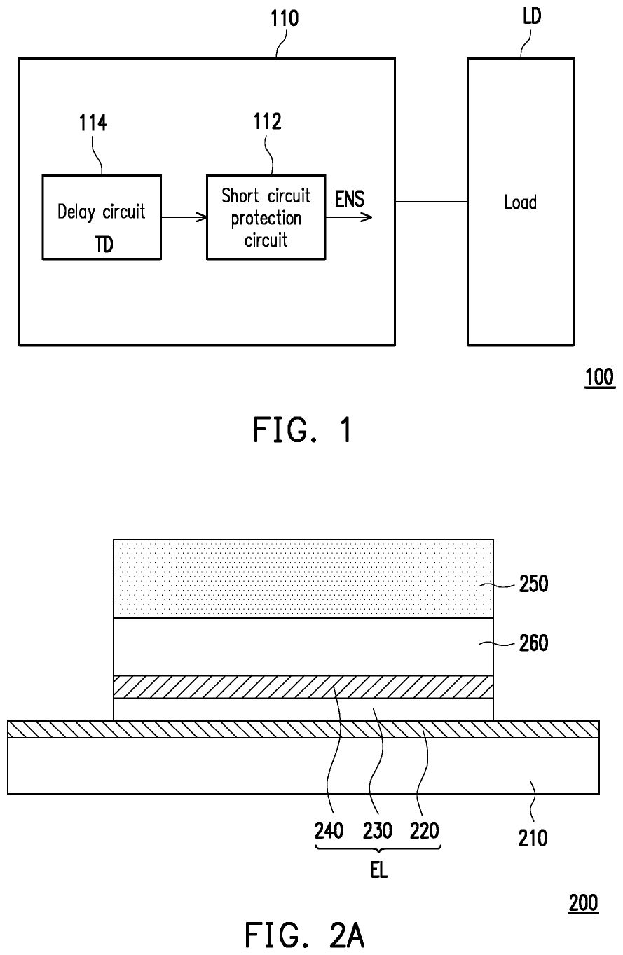

Please refer to FIG. 1. FIG. 1 is a schematic view of an organic semiconductor device according to a first embodiment of the present disclosure. The organic semiconductor device 100 of the first embodiment includes a load LD and a driving device 110. The load LD includes elements of organic materials having semiconductor properties, such as an Organic Light-Emitting Diode (OLED), an organic solar cell, and an Organic Field-Effect Transistor (OFET) and other elements. The driving device 110 is coupled to the load LD and configured to drive the load LD. The driving device 110 includes a short circuit protection circuit 112 and a delay circuit 114. The short circuit protection circuit 112 is configured to provide the enable signal ENS. The delay circuit 114 provides a delay time length TD according to the energy passing through the load LD. Moreover, the delay circuit 114 determines the start time point of the short circuit protection circuit 112 to provide the enable signal ENS according to the delay time length TD, so that the organic semiconductor device 100 can provide the corresponding mechanism for dealing with short-circuit through the enable signal ENS when regional short-circuit occurs to the load LD. In the present embodiment, the load LD has a heat-shrinkable film. The heat-shrinkable film is shrank due to the endothermic reaction caused by thermal energy, resulting in a structural change of the load LD. When the load LD produces a structural change, it performs a self-repairing function. The embodiment performs the mechanism for dealing with short-circuit through the structural change of the load LD after the regional short-circuit is occurred to the load LD.

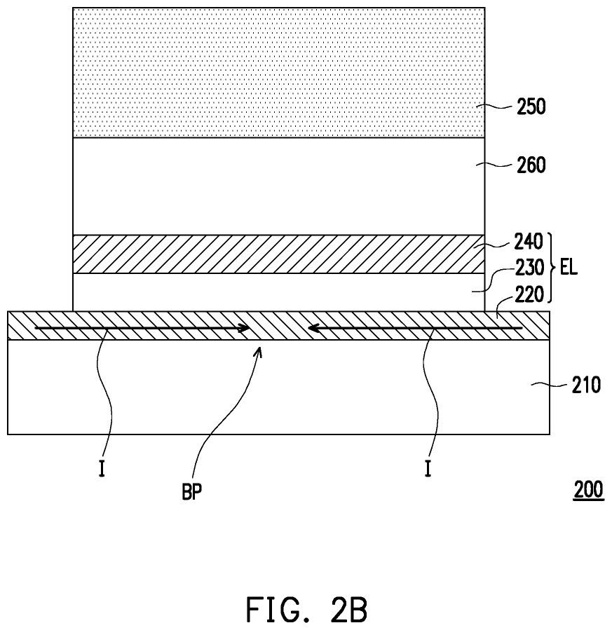

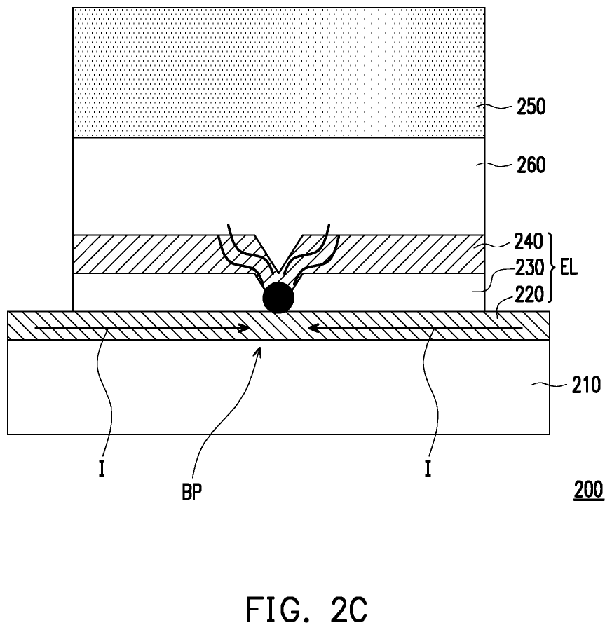

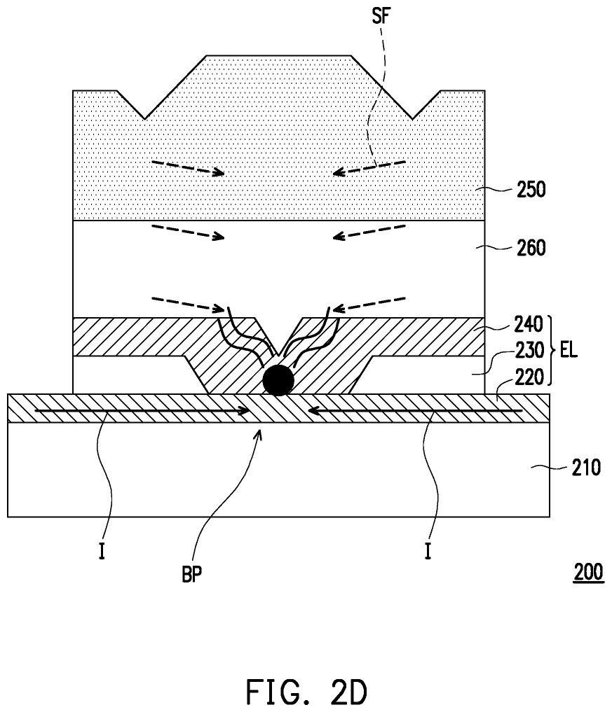

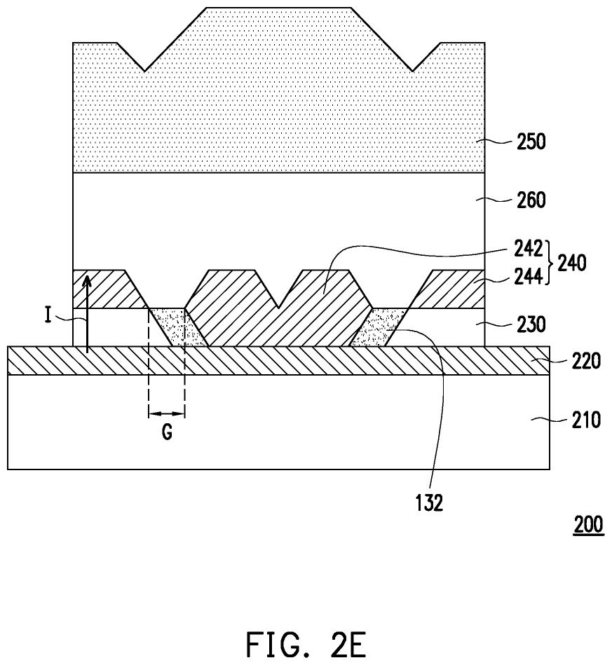

For example, the load is a light-emitting element including an organic light-emitting diode. FIG. 2A to FIG. 2E schematically illustrate the self-repairing function performed by a heat-shrinkable film in a light-emitting element. In FIG. 2A, the light-emitting element 200 includes a substrate 210, a first electrode 220, a light-emitting layer 230, a second electrode 240, a heat-shrinkable film 250, and a first adhesive layer 260. The first electrode 220 is disposed on the substrate 210, the light-emitting layer 230 is disposed on the first electrode 220, the second electrode 240 is disposed on the light-emitting layer 230, and the heat-shrinkable film 250 is disposed on the second electrode 240. The first electrode 220, the light-emitting layer 230, and the second electrode 240 are sequentially stacked on the substrate 210 to constitute the light-emitting unit EL. In addition, the first adhesive layer 260 is disposed between the heat-shrinkable film 250 and the second electrode 240 to attach the heat-shrinkable film 250 to the light-emitting unit EL.

FIG. 2B shows that when the light-emitting element 200 is turned on, the light-emitting element 200 has an abnormal point BP. At this time, the current I will be concentrated toward the abnormal point BP, so that the current density at the abnormal point BP is higher than other parts, which causes more heat to be generated at the abnormal point BP than other regions. Next, as shown in FIG. 2C, the light-emitting layer 230 is collapsed or partially burned out at the abnormal point BP, which causes the distance between the second electrode 240 and the first electrode 220 to be reduced, which will cause the concentration of the current I to be more severe. Since the current I is mostly concentrated at the abnormal point BP, in FIG. 2D, an increase in temperature at the abnormal point BP may cause the heat-shrinkable film 250 to shrink. On this occasion, the shrinkage stress SF of the heat-shrinkable film 250 may pull the second electrode 240 such that the partial portion of the second electrode 240 corresponding to the abnormal point BP is also deformed.

In FIG. 2E, the partial portion of the second electrode 240 corresponding to the abnormal point BP continues to shrink and deform under the shrinkage stress SF of the heat-shrinkable film 250 to be finally broken. On this occasion, the second electrode 240 may include the independent electrode pattern 242 and the effective electrode portion 244, and the effective electrode portion 244 and the independent electrode pattern 242 are separated by the electrode gap G such that the effective electrode portion 244 and the independent electrode pattern 242 are structurally two parts that are independent of each other and electrically isolated from each other. The independent electrode pattern 242 may be in contact with the first electrode 120, but a coked light-emitting layer material may be present therebetween. After the independent electrode pattern 242 forms a completely independent conductive pattern, power supply is continuously applied to the light-emitting element 200, the current I will not flow through the independent electrode pattern 242 and will be uniformly transmitted between the first electrode 120 and the effective electrode portion 244 of the second electrode 240. Effective light emission may be generated in the area range of the effective electrode portion 244 of the second electrode 240.

It can be seen from the above that the structural change of the load is related to the shrinkage reaction caused by the heat-shrinkable film 250 encountering thermal energy. The delay time length is associated with the rate of the structural change. The delay time length is set to be longer than the length of time between the start of collapse or partial burnout (e.g., FIG. 2C) at the abnormal point BP and the occurrence of the effective electrode portion 244 and the independent electrode pattern 242 (e.g., FIG. 2E). That is, the delay time length may be set to be greater than or equal to the length of time between the load starting to be short-circuited and self-repaired to effectively emit light. For example, the length of time between occurrence of short-circuit and self-repaired to effectively emit light is less than 1.5 seconds, then the delay time length may be set to be equal to 1.5 seconds.

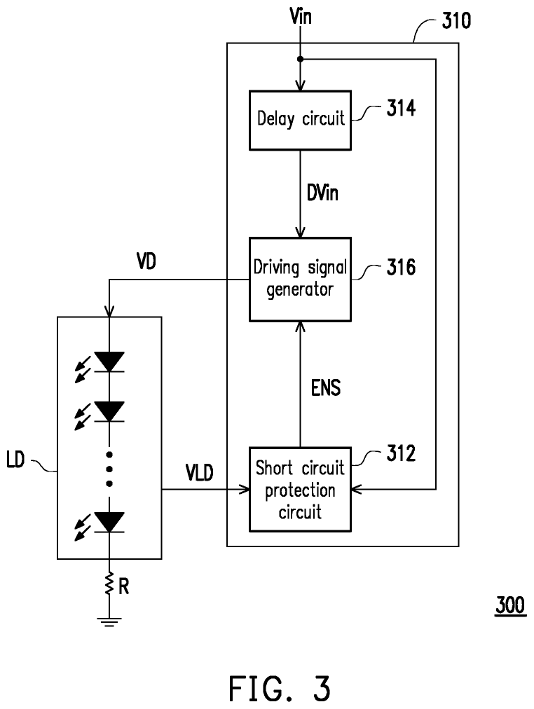

Please refer to FIG. 3. FIG. 3 is a schematic view of an organic semiconductor device according to a second embodiment of the present disclosure. In the present embodiment, the load LD is a light-emitting element including at least one organic light-emitting diode. In the case where the load LD includes a plurality of organic light-emitting diodes, the plurality of organic light-emitting diodes are coupled to each other in series. For example, the cathode of a first-stage organic light-emitting diode in a plurality of organic light-emitting diodes is connected to the anode of a second-stage organic light-emitting diode, the cathode of the second-stage organic light-emitting diode is connected to the anode of the third-stage organic light-emitting diode, and so on. The load LD at least has a high voltage terminal, a sensing terminal, and a low voltage terminal. The high voltage terminal is connected to the anode of the first-stage organic light-emitting diode. The sensing terminal may be connected to the cathode of one of the at least one organic light-emitting diode. The low voltage terminal may be coupled to a low level (e.g., a ground level) through a resistor R.

In the present embodiment, the driving device 310 of the organic semiconductor device 300 of the second embodiment includes a short circuit protection circuit 312, a delay circuit 314, and a driving signal generator 316. The short circuit protection circuit 312 receives the power supply Vin. The power supply Vin is an external power supply in the form of direct current or a direct current power supply converted by an external power supply in the form of an alternating current. The delay circuit 314 also receives power supply Vin and provides a delayed power supply DVin according to the delay time length. In other words, the rise time (e.g., the low voltage level of the power supply is rose to the high voltage level) of the delayed power supply DVin has a time delay compared to the rise time of the power supply Vin. In addition, as will be understood from the description of FIG. 2A to FIG. 2E, the above-described delay time length is set in relation to the rate of structural change of the load LD, and therefore, the time point at which the driving signal generator 316 is driven according to the delayed power supply DVin is the time point at which the organic light-emitting diode is self-repaired to effectively emit light, or after a time point of being self-repaired to effectively emit light.

The driving signal generator 316 receives the delayed power supply DVin, thereby delaying the supply of the driving signal to the load LD. In this embodiment, the driving signal generator 316 is configured to drive the voltage VD to the high voltage terminal of the load LD. The load LD is driven by the driving voltage VD received by the high voltage terminal of the load LD itself. In some embodiments, the driving signal generator 316 receives the delayed power supply DVin, thereby delaying the supply of the driving current (not shown) to the high voltage terminal of the load LD to drive the load LD.

The short circuit protection circuit 312 receives the load voltage VLD through the sensing terminal of the load LD, and determines whether the load LD is short-circuited by the voltage value of the load voltage VLD. For example, the load LD is a light-emitting element including at least one organic light-emitting diode, and assuming that the voltage value of the driving voltage VD is 24V, and the forward bias value inside the load LD is 11V under the condition that the load LD effectively emits light. Therefore, in the condition of effective light emission, the voltage value of the load voltage VLD is substantially close to the difference between the voltage value of the driving voltage VD and the forward bias value, that is, the voltage value of the load voltage VLD is substantially close to 13V. If the voltage value of the load voltage VLD is close to 13V, the short circuit protection circuit 312 determines that the load LD is not short-circuited. On the other hand, when the voltage value of the load voltage VLD is significantly larger than 13V, for example, 20V, it means that the load LD is short-circuited inside and thus the forward bias value is decreased, and the short circuit protection circuit 312 determines that the load LD is short-circuited according to the significant rise of the voltage value of the load voltage VLD.

When the short circuit protection circuit 312 determines that the load LD is short-circuited, the enable signal ENS having the first voltage level is supplied to the driving signal generator 316. When receiving the enable signal ENS having the first voltage level, the driving signal generator 316 stops supplying the driving voltage VD, thereby stopping the driving of the load LD. In this case, the organic semiconductor device 300 can be restarted again. Since the driving signal generator 316 receives the delayed power supply DVin when the organic semiconductor device 300 is restarted, driving of the load LD is delayed according to the delay time length, and is delayed to be driven until the self-repairing of the load LD is completed to achieve effective light emission.

On the other hand, when the short circuit protection circuit 312 determines that the load LD is not short-circuited, there is the enable signal ENS having the second voltage level, and the voltage value of the load voltage VLD is received continuously to determine whether the load LD is short-circuited. The first voltage level is different from the second voltage level. The driving signal generator 316 continues to supply the driving voltage VD to drive the load LD in the case of receiving the enable signal ENS having the second voltage level. That is, the short circuit protection circuit 312 supplies a corresponding enable signal ENS according to the voltage value of the load voltage VLD to control the driving signal generator 316 to drive the load LD or stop driving the load LD.

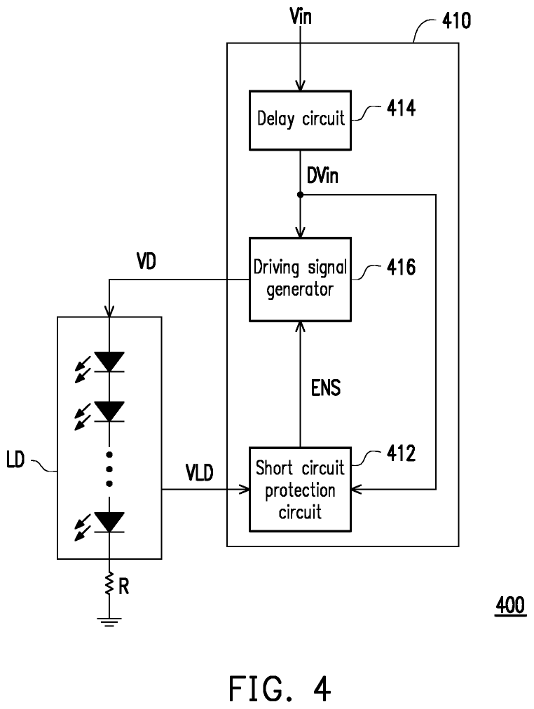

Please refer to FIG. 4. FIG. 4 is a schematic view of an organic semiconductor device according to a third embodiment of the present disclosure. The driving device 410 of the organic semiconductor device 400 of the third embodiment includes a short circuit protection circuit 412, a delay circuit 414, and a driving signal generator 416. For details of the implementation of the driving signal generator 416, reference may be made to the driving signal generator 316 described in the second embodiment. Unlike the second embodiment, the short circuit protection circuit 412 receives the delayed power supply DVin supplied by the delay circuit 414. As a result, when the organic semiconductor device 400 is restarted, the short circuit protection circuit 412 and the driving signal generator 416 receive the delayed power supply DVin. Therefore, driving of the load LD is delayed according to the delay time length. Further, driving of the short circuit protection circuit 412 is also delayed to determine whether or not the load LD is short-circuited.

The delay time length supplied by the delay circuit 414 is set in relation to the rate of structural change of the load LD. Therefore, the time point at which the short circuit protection circuit 412 and the driving signal generator 416 are driven according to the delayed power supply DVin is a time point at which the organic light-emitting diode is self-repaired to effectively emit light, or after a time point of being self-repaired to effectively emit light.

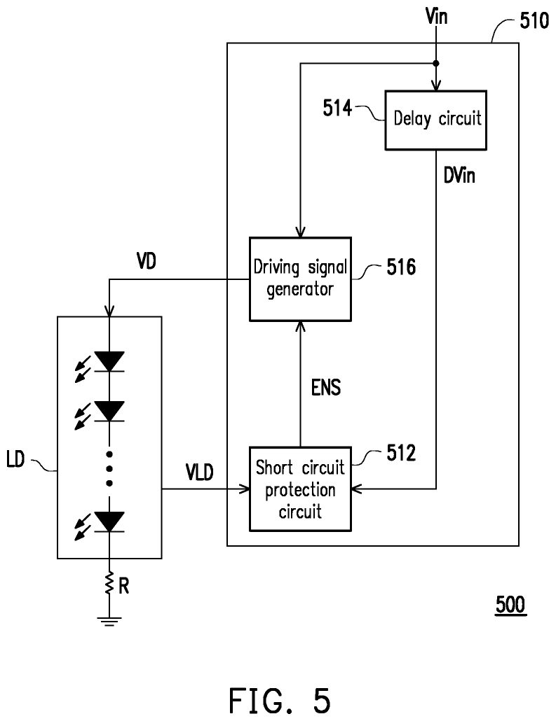

Please refer to FIG. 5. FIG. 5 is a schematic view of an organic semiconductor device according to a fourth embodiment of the present disclosure. The driving device 510 of the organic semiconductor device 500 of the fourth embodiment includes a short circuit protection circuit 512, a delay circuit 514, and a driving signal generator 516. The fifth embodiment is different from the third embodiment (FIG. 4) in that the driving signal generator 516 of the fifth embodiment receives the power supply Vin instead of receiving the delayed power supply DVin. The delay time length supplied by the delay circuit 514 is set in relation to the rate of structural change of the load LD. Therefore, the time point at which the short circuit protection circuit 512 is driven according to the delayed power supply DVin is a time point at which the organic light-emitting diode is self-repaired to effectively emit light, or after a time point of being self-repaired to effectively emit light.

From the second embodiment to the fourth embodiment (FIG. 3 to FIG. 5), it is shown that the delay circuit may be selected to be coupled to the driving signal generator (FIG. 3), and the delay circuit may be selected to be coupled to the short circuit protection circuit (e.g., FIG. 5). In addition, the delay circuit may also be selected to be coupled to the short circuit protection circuit (e.g., FIG. 4). In other words, the delay circuit may be coupled to at least one of the driving signal generator and the short circuit protection circuit, and supply the delayed power supply to at least one of the driving signal generator and the short circuit protection circuit according to the delay time length.

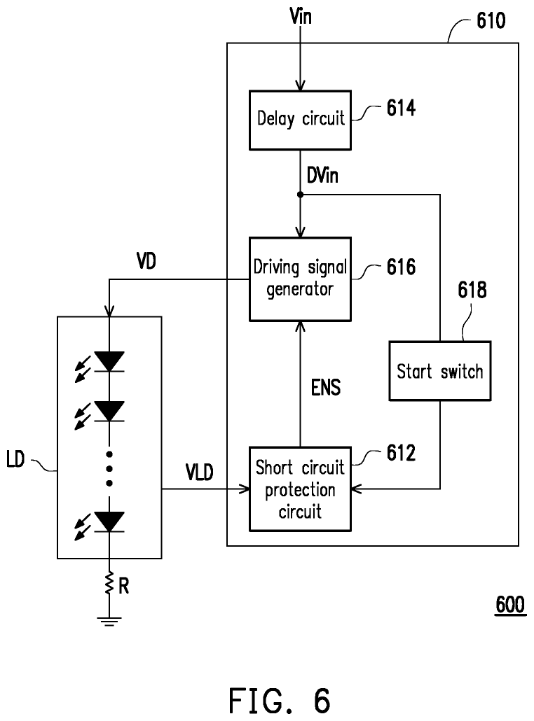

Please refer to FIG. 6. FIG. 6 is a schematic view of an organic semiconductor device according to a fifth embodiment of the present disclosure. The driving device 610 of the organic semiconductor device 600 of the fifth embodiment includes a short circuit protection circuit 612, a delay circuit 614, and a driving signal generator 616, and further includes a start switch 618. The start switch 618 is coupled between the delay circuit and the short circuit protection circuit 612. The start switch 618 is configured to drive the short circuit protection circuit 612 according to the delayed power supply DVin.

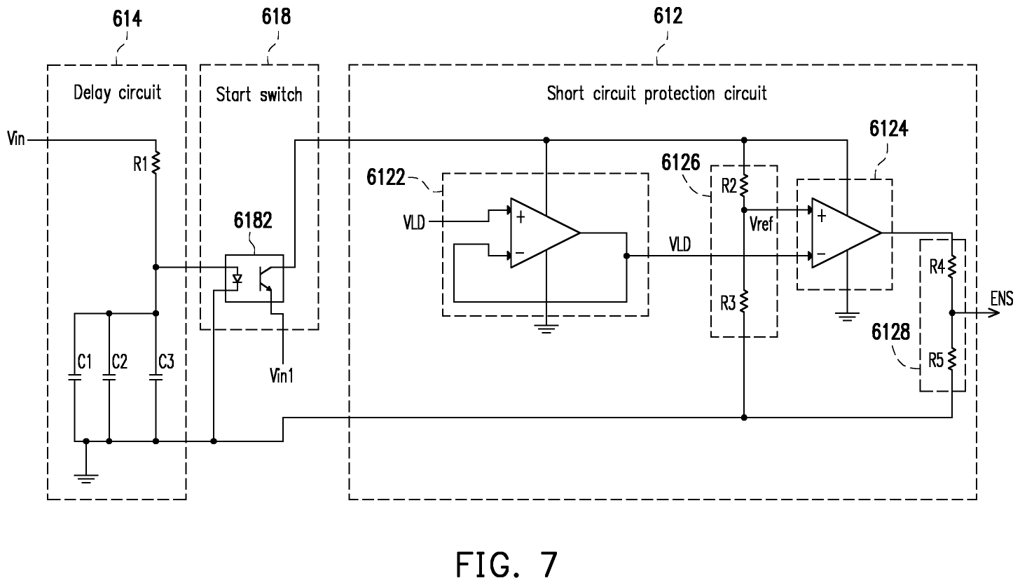

For further explanation, please refer to FIG. 6 and FIG. 7. FIG. 7 is a schematic view of a delay circuit 614, a start switch 618, and a short circuit protection circuit 612 according to a fifth embodiment. In the present embodiment, the delay circuit 614 may be, for example but not limited to, a resistive capacitance delay circuit. The delay circuit 614 of this embodiment includes a resistor R1 and capacitors C1 to C3. The first end of the resistor R1 is for receiving the power supply Vin. The second end of the resistor R1 is coupled to the first ends of the capacitors C1 to C3 and is configured to output the delayed power supply DVin. The second ends of the capacitors C1 to C3 are coupled to a low level (for example, a ground level). In this embodiment, the delay circuit 614 may adjust the configuration or the number of the resistor R1 and the capacitors C1 to C3 according to the setting or the requirement of the delay time length, or adjust the resistance value of the resistor R1 and the capacitance value of the capacitors C1 to C3. In this embodiment, the resistor R1 may be any type of resistor or variable resistor, and the capacitors C1 to C3 may be any type of capacitor or variable capacitor.

The start switch 618 is coupled between the delay circuit 614 and the short circuit protection circuit 612. The start switch 618 may include an optical coupler 6182. The first end of the optical coupler 6182 is configured to receive the delayed power supply DVin supplied by the delay circuit 614. The second end of the optical coupler 6182 is coupled to a low level (e.g., a ground level). The third end of the optical coupler 6182 is coupled to another power supply Vin1. The fourth end of the optical coupler 6182 is coupled to the short circuit protection circuit 612. The start switch 618 receives the delayed power supply DVin and generates an optical signal according to the delayed power supply DVin. When the delayed power supply DVin reaches a predetermined high level, the start switch 618 is turned on, and the power supply Vin1 is supplied to the short circuit protection circuit 612. The high voltage level of the power supply Vin1 may be different (or the same) as the high voltage level of the delayed power supply DVin. As such, the short circuit protection circuit 612 may be driven at a high voltage level different from the delayed power supply DVin.

In the present embodiment, the short circuit protection circuit 612 includes a buffer 6122, an operational amplifier 6124, a voltage divider 6126, and an output circuit 6128. The input terminal of the buffer 6122 is configured for receiving the load voltage VLD. The buffer 6122 of the present embodiment may be, for example but not limited to, a unigain buffer. The buffer 6122 is configured for supplying power with a sustain load voltage VLD. The voltage divider 6126 includes resistors R2, R3. The first end of the resistor R2 is configured for receiving the power supply Vin1. The second end of the resistor R2 is coupled to the first end of the resistor R3. The second end of the resistor R3 is coupled to a low level (e.g., a ground level). The voltage divider 6126 divides the voltage value of the power supply Vin1 to generate a reference voltage value Vref (e.g., 15V). The voltage divider 6126 supplies a reference voltage value Vref to the operational amplifier 6124 through a second end of the resistor R2.

The inverting input terminal of the operational amplifier 6124 is coupled to the output terminal of the buffer 6122. The non-inverting input terminal of the operational amplifier 6124 is configured for receiving the reference voltage value Vref provided by the voltage divider 6126. The output terminal of operational amplifier 6124 is configured to provide an output voltage value. The operational amplifier 6124 compares the reference voltage value Vref with the voltage value of the load voltage VLD to obtain a comparison result. If the comparison result indicates that the voltage value of the load voltage VLD is greater than the reference voltage value Vref, the operational amplifier 6124 provides an output voltage value (for example, 0V) having a low voltage level, which means that the load LD is short-circuited when the voltage value of the load voltage VLD is greater than the reference voltage value Vref. The operational amplifier 6124 provides an output voltage value having a low voltage level in the event that the load LD is short-circuited.

On the other hand, if the comparison result indicates that the voltage value of the load voltage VLD is less than or equal to the reference voltage value Vref, the operational amplifier 6124 provides an output voltage value (for example, 24 V) having a high voltage level, which means that the load LD is not short-circuited in the case where the voltage value of the load voltage VLD is less than or equal to the reference voltage value Vref. The operational amplifier 6124 provides an output voltage value of a high voltage level in the event that the load LD is short-circuited.

The output circuit 6128 includes resistors R4, R5. The first end of the resistor R4 is configured for receiving an output voltage value. The second end of the resistor R4 is coupled to the first end of the resistor R5. The second end of the resistor R5 is coupled to a low level (e.g., a ground level). The output circuit 6128 divides the output voltage value to generate an enable signal ENS.

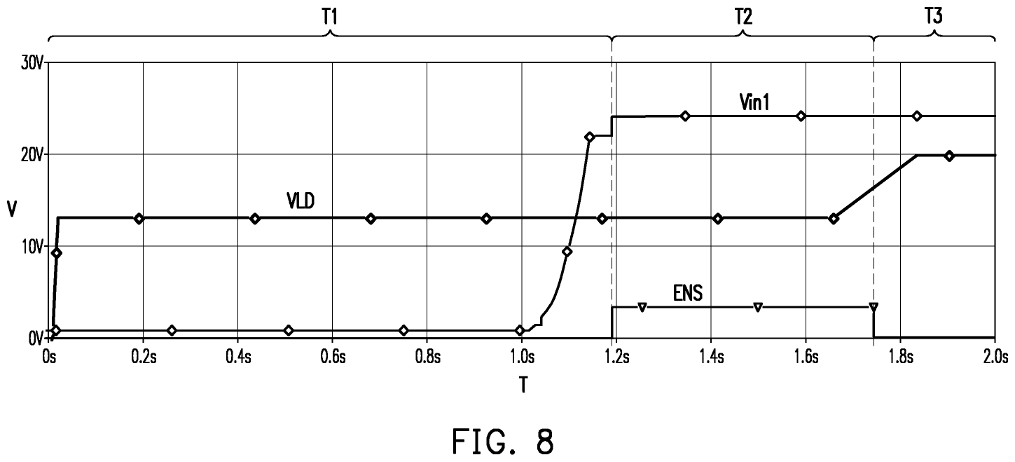

Please refer to FIG. 6, FIG. 7 and FIG. 8. FIG. 8 is a schematic waveform diagram of the power supply Vin1, the load voltage VLD, and the enable signal ENS according to the embodiment of FIG. 7. In the schematic diagram, the vertical axis is expressed as voltage (V) in volts. The horizontal axis is expressed as time (T) in seconds. In the present embodiment, in the time interval T1, the start switch 618 receives the delayed power supply DVin, thereby delaying by 1 second to start supplying the power supply Vin1. Next, in the time interval T2, the short circuit protection circuit 612 is driven by the power supply Vin1. After the short circuit protection circuit 612 is driven, it is determined whether the voltage value of the load voltage VLD is greater than the reference voltage value Vref (for example, 13 to 15 V).

The short circuit protection circuit 612 determines in the time interval T2 that the voltage value of the load voltage VLD is 13V. Therefore, in the case where the voltage value of the load voltage VLD is smaller than the reference voltage value Vref, the operational amplifier 6124 provides an output voltage value having a high voltage level, and the output circuit 6128 divides the output voltage value having a high voltage level to generate an enable signal ENS (for example, 3-5V) with a logical high level. In this way, the driving signal generator 616 receives the enable signal ENS having a logical high level, and continuously provides the driving voltage VD according to the logical high level of the enable signal ENS.

When the load LD is short-circuited, the voltage value of the load voltage VLD starts to increase. In the time interval T3, the short circuit protection circuit 612 determines that the voltage value of the load voltage VLD is greater than the reference voltage value Vref. The operational amplifier 6124 provides an output voltage value having a low voltage level and generates an enable signal ENS (e.g., 0V) having a logical low level. In this way, the driving signal generator 616 receives the enable signal ENS having a logical low level, and stops providing the driving voltage VD according to the logical low level of the enable signal ENS. In some embodiments, the driving signal generator 616 may stop providing the driving voltage VD according to the falling edge (i.e., the time point at which the enable signal ENS falls to a logical low level from a logical high level) of the enable signal ENS.

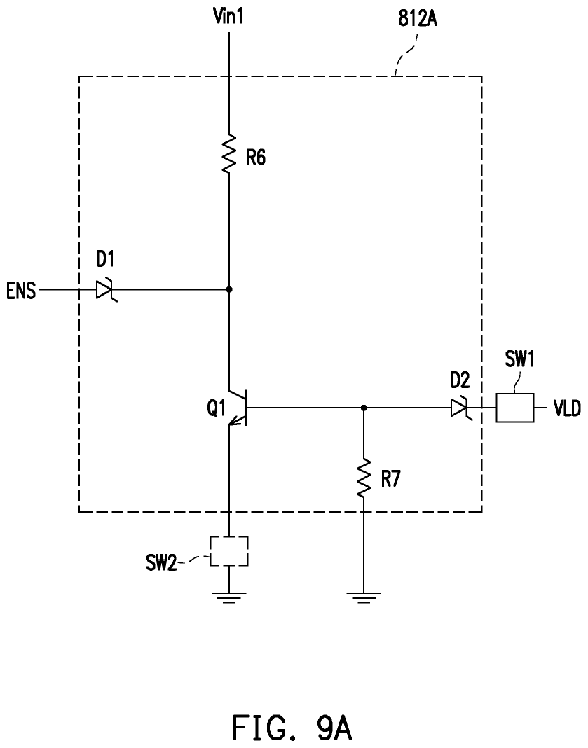

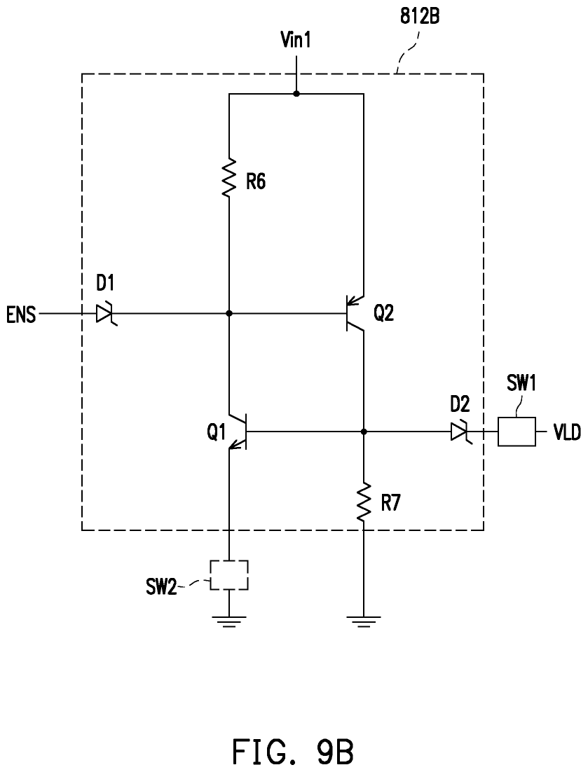

Please refer to FIG. 9A. FIG. 9A is a schematic view of another short circuit protection circuit according to the fifth embodiment of the present disclosure. The short circuit protection circuit 812A of the present embodiment includes a diode D1, resistors R6 and R7, and a switch Q1. In this embodiment, the first end of the resistor R6 is configured to receive the power supply Vin1. The first end of the switch Q1 is coupled to the second end of the resistor R6. The second end of the switch Q1 is coupled to the reference low power supply. The diode D1 is coupled to the first end of the switch Q1. The first end of the resistor R7 is coupled to the control terminal of the switch Q1. The second end of the resistor R7 is coupled to the reference low power supply. The diode D1 may be implemented by a Zener diode, and the cathode of the diode D1 is coupled to the first end of the switch Q1. The switch Q1 may be realized by an npn type Bipolar Junction Transistor (BJT). In this embodiment, the short circuit protection circuit 812A receives the load voltage VLD from the load through the first end of the resistor R7, and provides the enable signal ENS through the first end of the switch Q1 and the diode D1.

In the embodiment, the short circuit protection circuit 812A may further include a diode D2. The diode D2 may be implemented by a Zener diode, and the anode of the diode D2 is coupled to the control terminal of the switch Q1.

In the present embodiment, when the voltage value of the load voltage VLD is low and not enough to turn on the switch Q1, the switch Q1 is in an off state. The voltage at the first end of the switch Q1 may be at a high voltage level, so the voltage value of the enable signal ENS is at a logical high level. When the voltage value of the load voltage VLD is not enough to turn on the switch Q1, the voltage at the first end of the switch Q1 is pulled low to a low voltage level, so the voltage value of the enable signal ENS is a logical low level. That is, when the load is not short-circuited, the voltage value of the load voltage VLD does not turn on the switch Q1 of the short circuit protection circuit 812A. Therefore, the short circuit protection circuit 812A provides the enable signal ENS having a logical high level, thereby causing the driving device to drive the load LD. When the load is short-circuited, the voltage value of the load voltage VLD rises and is sufficient to turn on the switch Q1 of the short circuit protection circuit 812A, so the short circuit protection circuit 812A provides the enable signal ENS with a logical low level, thereby making the driving device to stop driving the load LD. In addition, the short circuit protection circuit 812A in this embodiment can determine the logical level of the enable signal ENS according to the voltage value of the load voltage VLD and the voltage value of the power supply Vin1 without adding the reference voltage value of the sixth embodiment for making judgment.

In the present embodiment, the delay switch SW1 (which may be, for example, a start switch) may be disposed in the short circuit protection circuit 812A at the cathode of the diode D2. When the power supply Vin1 is activated, the delay switch SW1 is delayed in conduction due to the delayed start of the power supply, so the voltage value of the load voltage VLD does not affect the on or off of the switch Q1 of the short circuit protection circuit 812A. Therefore, the short circuit protection circuit 812A provides the enable signal ENS having the logical high level, thereby causing the driving device to drive the load LD. Until the delay switch SW1 delays to finish, the diode D2 is turned on, and the load voltage VLD will begin to affect the on or off of the switch Q1.

In other embodiments, the delay switch SW2 (which may be, for example, a start switch) may be disposed between the second end of the switch Q1 and the reference low power supply. When the power supply Vin1 is started, the delay switch SW2 is delayed in conduction due to the power supply is delayed to start, so no matter whether the input of the voltage of the load voltage VLD is sufficient to turn on the switch Q1 of the short circuit protection circuit 812A, the second end of the switch Q1 will not be connected to the reference low power supply. Therefore, the short circuit protection circuit 812A provides the enable signal ENS having a logical high level, thereby causing the driving device to drive the load LD. Until the delay switch SW2 delays to finish, the second end of the switch Q1 is turned on to generate the path from the switch Q1 to the reference low power supply.

Please refer to FIG. 9B. FIG. 9B is a schematic view of still another short circuit protection circuit according to the fifth embodiment of the present disclosure. Unlike the short circuit protection circuit 812A of FIG. 9A, the short circuit protection circuit 812B of the present embodiment further includes a switch Q2. The first end of the switch Q2 is configured to receive the power supply Vin1. The first end of the switch Q2 is configured to receive the power supply Vin1. The second end of the switch Q2 is coupled to the first end of the resistor R7 and the control terminal of the switch Q1. The control terminal of the switch Q2 is coupled to the first terminal of the switch Q1. The switch Q2 may be implemented by a pnp type bipolar junction type transistor.

In the present embodiment, when the short circuit protection circuit 812B receives the load voltage VLD of a lower voltage value, the switch Q1 is in an off state. The voltage at the first end of the switch Q1 is at a high voltage level, so the voltage value of the enable signal ENS is at a logical high level. Meanwhile, the switch Q2 is turned off through the high voltage level at the first end of switch Q1. Therefore, in the case of the load voltage VLD having a lower voltage value, the enable signal ENS provided by the short circuit protection circuit 812B can be maintained at a logical high level. When the voltage value of the load voltage VLD is increased to turn on the switch Q1, the voltage at the first end of the switch Q1 is at a low voltage level, so the voltage value of the enable signal ENS is a logical low level. Meanwhile, the switch Q2 is turned on through the low voltage level at the first end of switch Q1. The control terminal of switch Q1 will receive the voltage value of the high voltage level, so the switch Q1 will remain in the on state. Therefore, the transistors Q1 and Q2 can form a latching loop. When the voltage value of the load voltage VLD decreases, the control terminal of the switch Q1 maintains at a higher voltage level, and the enable signal ENS provided by the short circuit protection circuit 812B can be maintained at a logical low level.

In some embodiments, the delay switch SW1 may be disposed in the short circuit protection circuit 812A at the cathode of the diode D2. In other embodiments, the delay switch SW2 (which may be, for example, a start switch) may be disposed between the second end of the switch Q1 and the reference low power supply. The implementation details of the delay switches SW1, SW2 may be adequately taught in the embodiment of FIG. 9A and therefore will not be repeated here.

The short circuit protection circuit 812A of FIG. 9A and the short circuit protection circuit 812B of FIG. 9B are not only adaptable for the organic semiconductor device 600 of the fifth embodiment, under the premise that the short circuit protection circuit 812 is designed to receive the delayed power supply DVin or the power supply Vin, they are also adaptable for the organic semiconductor devices 100, 300 to 500 of the first to fourth embodiments.

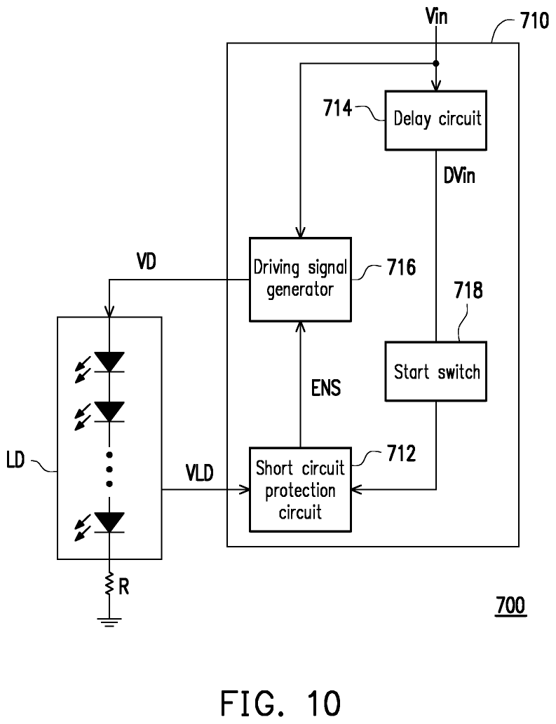

Please refer to FIG. 10, FIG. 10 is a schematic view of an organic semiconductor device according to the sixth embodiment of the present disclosure. The driving device 710 of the organic semiconductor device 700 includes a short circuit protection circuit 712, a delay circuit 714, a driving signal generator 716, and a start switch 718. The sixth embodiment is different from the fifth embodiment (FIG. 6) in that the driving signal generator 716 of the sixth embodiment receives the power supply Vin instead of receiving the delayed power supply DVin. For details of the implementation of the short circuit protection circuit 712, the delay circuit 714, the driving signal generator 716, and the start switch 718, please refer to the teachings of the fifth embodiment (e.g., FIG. 6 to FIG. 8), and related descriptions will not be repeated here.

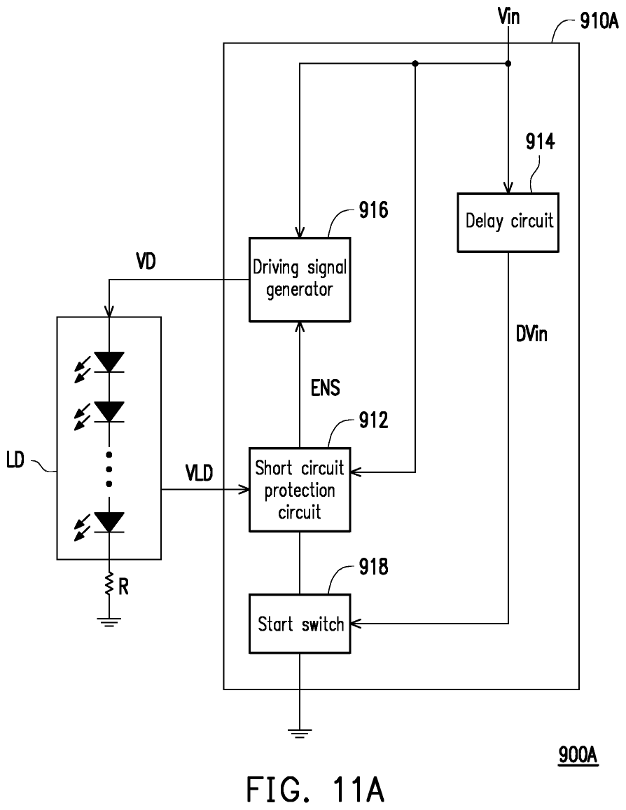

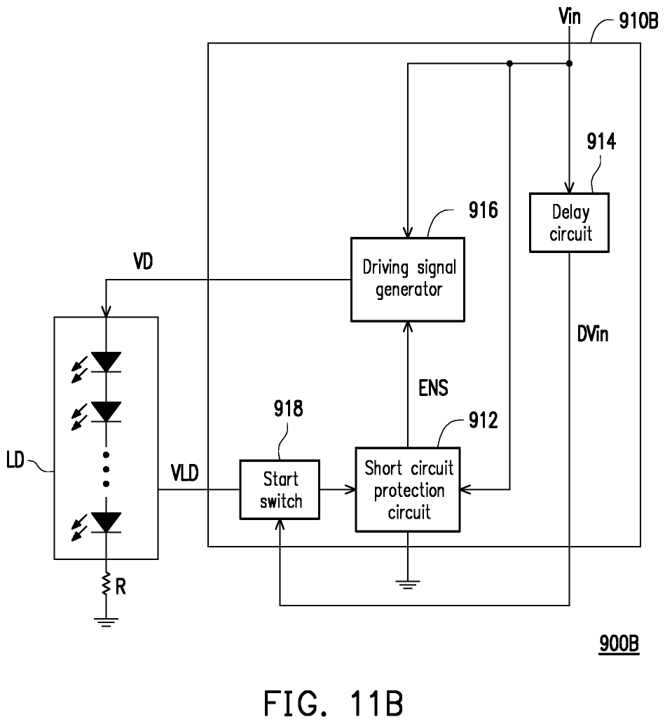

Please refer to FIG. 11A, FIG. 11A is a schematic view of an organic semiconductor device according to a seventh embodiment of the present disclosure. In the present embodiment, the driving device 910 of the organic semiconductor device 900A includes a short circuit protection circuit 912, a delay circuit 914, a driving signal generator 916, and a start switch 918. Different from the sixth embodiment (FIG. 10), the short circuit protection circuit 912 receives the power supply Vin, and the start switch 918 is also coupled to the reference low power supply (for example, ground). The start switch 918 turns off the switch loop in the open circuit protection inside the short circuit protection circuit 912 when the delayed power supply DVin has not yet activated the power supply. On the other hand, the start switch 918 establishes the switch loop in the open circuit protection inside the short circuit protection circuit 912 when the delayed power supply DVin has activated the power supply. The implementation details of the short circuit protection circuit 912 and the start switch 918 may be adequately taught in the embodiment of FIG. 9A (short circuit protection circuit 812A and delay switch SW2) and therefore related descriptions will not be repeated here.

Please refer to FIG. 11B, FIG. 11B is a schematic view of an organic semiconductor device according to an eighth embodiment of the present disclosure. In the present embodiment, the driving device 910 of the organic semiconductor device 900B includes a short circuit protection circuit 912, a delay circuit 914, a driving signal generator 916, and a start switch 918. Different from the seventh embodiment (FIG. 11A), the start switch 918 of the present embodiment is disposed between the load LD and the short circuit protection circuit 912. The start switch 918 turns off the loop of the short circuit protection circuit 912 for receiving the load voltage VLD when the delayed power supply DVin has not yet activated the power supply. On the other hand, the start switch 918 establishes the loop of the short circuit protection circuit 912 for receiving the load voltage VLD when the delayed power supply DVin has activated the power supply. The implementation details of the short circuit protection circuit 912 and the start switch 918 of the present embodiment may be sufficiently taught in the embodiment of FIG. 9A (the short circuit protection circuit 812A and the delay switch SW1), and therefore related descriptions will not be repeated here.

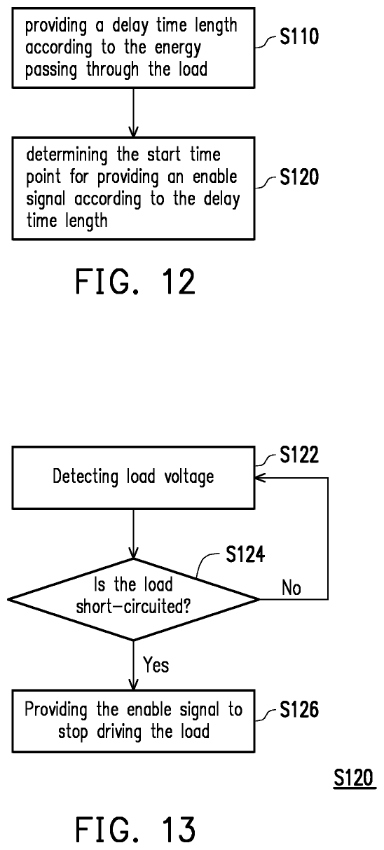

Please refer to FIG. 1 and FIG. 12, FIG. 12 is a flow chart of a driving method according to an embodiment of the disclosure. In step S110, the delay time length TD is provided according to the energy passing through the load LD. In step S120, the start time point of providing the enable signal ENS is determined according to the delay time length TD. The implementation details of the above steps may be sufficiently taught by the description of the embodiment of FIG. 1, and related descriptions will not be repeated here.

Please refer to FIG. 3, FIG. 12 and FIG. 13, FIG. 13 is a flow chart of a driving method according to step S120. The step S120 further includes steps S122, S124, and S126. In step S122, the load voltage VLD is detected. In step S124, it is determined whether or not the load LD is short-circuited according to the voltage value of the load voltage VLD. When it is determined that the load LD is short-circuited, the process proceeds to step S126. In step S126, the enable signal ENS (for example, the enable signal ENS of a low voltage level) is provided to stop driving the load LD. When it is determined in step S124 that the load LD is not short-circuited, the process returns to step S122. The implementation details of the above steps may be sufficiently taught by the description of the embodiment of FIG. 3 to FIG. 8 and related descriptions will not be repeated here.

In some embodiments, the delay circuit is further configured to instruct, through the continuing time length of occurrence of short-circuit being longer than the delay time length, the short circuit protection circuit to provide the enable signal for stopping driving the load, such that the driving device stops driving the load.

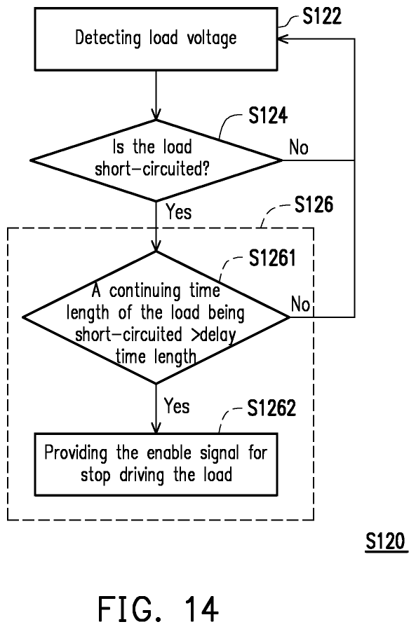

Further, please refer to FIG. 4, FIG. 13, and FIG. 14. FIG. 14 is a flow chart of another driving method according to step S120. In the embodiment, step S126 includes steps S1261 and S1262. When the short-circuit protection circuit detects the load voltage VLD in step S122 and determines that the load LD is short-circuited in step S124, the delay circuit 414 may further determine in step S1261 whether the continuing time length of the load LD being short-circuited is longer than the delay time length. If the delay circuit 414 determines that the continuing time length is less than or equal to the delay time length, the process returns to step S122 such that the short circuit protection circuit 412 continues detecting the load voltage VLD.

On the other hand, if the delay circuit 414 determines that the continuing time length is longer than the delay time length, this means that the load LD is not self-repaired through the heat-shrinkable film during the delay time length. Then, the process proceeds to step S1262, the delay circuit 414 will instruct the short circuit protection circuit 412 to provide the enable signal ENS (for example, the enable signal ENS of a low voltage level) for stopping driving the load LD. That is to say, the delay circuit 414 may determine the start time point of the short circuit protection circuit 412 to provide the enable signal ENS according to the continuing time length and the delay time length. Therefore, in the configuration design of the delay circuit 414, the delay circuit 414 may be coupled to the short circuit protection circuit 412 (as shown in FIG. 4, FIG. 5, FIG. 9), or may be disposed inside the short circuit protection circuit 412.

In these embodiments, the driving device 410 may also include a signal format converter (not shown). The signal format converter converts the load voltage VLD in the analog signal form into the load voltage VLD in the form of a digital signal, and supplies the load voltage VLD in the form of a digital signal to the short circuit protection circuit 412.

In summary, the organic semiconductor device of the present disclosure provides the delay time length associated with the structural change of the load itself through the energy of the load, and determines the start time point of providing the enable signal according to the delay time length. In this way, when the load is short-circuited, the organic semiconductor device can provide a corresponding mechanism for dealing with short-circuit according to the delay time length.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A driving device for driving a load, comprising:
a short circuit protection circuit configured for providing an enable signal; and
a delay circuit, providing a delay time length according to an energy passing through the load, and determines a start time point of the short circuit protection circuit to provide the enable signal according to the delay time length.

2. The driving device of claim 1, wherein the driving device further comprises:
a driving signal generator, configured to receive a power supply and provide a driving voltage or a driving current to the load.

3. The driving device of claim 2, wherein the delay circuit is further configured to receive the power supply, and provide the delayed power supply to at least one of the driving signal generator and the short circuit protection circuit according to the delay time length.

4. The driving device of claim 3, wherein the driving signal generator delays to provide the driving voltage or the driving current according to the delayed power supply.

5. The driving device of claim 3, wherein the delayed power supply is configured to drive the short circuit protection circuit.

6. The driving device of claim 3, further comprising:
a start switch, coupled between the delay circuit and the short circuit protection circuit for driving the short circuit protection circuit according to the delayed power supply.

7. The driving device of claim 6, wherein the start switch comprises an optical coupler.

8. The driving device of claim 3, wherein:
the short circuit protection circuit is driven by the power supply,
the driving device further comprising:
a start switch, coupled between the delay circuit and the short circuit protection circuit for making the short circuit protection circuit to provide the enable signal according to the delayed power supply.

9. The driving device of claim 8, wherein the start switch is further coupled to the load for establishing a loop making the short circuit protection circuit to receive a load voltage from the load according to the delayed power supply.

10. The driving device of claim 8, wherein the start switch is further coupled to a reference low power supply for connecting the short circuit protection circuit to the reference low power supply according to the delayed power supply, when the short circuit protection circuit is connected to the reference low power supply, a switch loop in an open circuit protection inside the short circuit protection circuit is established.

11. The driving device of claim 1, wherein the short circuit protection circuit comprises:
a buffer, an input terminal of the buffer is configured for receiving a load voltage from the load;
an operational amplifier, a non-inverting input terminal thereof configured for receiving a reference voltage value, an inverting input terminal of the operational amplifier coupled to an output terminal of the buffer, and an output terminal of the operational amplifier configured for providing an output voltage value;
a voltage divider, coupled to the non-inverting input terminal of the operational amplifier for receiving the power supply, and dividing a voltage value of the power supply to generate the reference voltage value; and
an output circuit, coupled to the output terminal of the operational amplifier for receiving the output voltage value, and dividing the output voltage value to generate the enable signal.

12. The short circuit protection driving device of claim 1, wherein the short circuit protection circuit comprises:
a diode;
a first resistor, a first end of the first resistor configured to receive the power supply;
a first switch, a first end of the first switch coupled to a second end of the first resistor and the diode, and a second end of the first switch coupled to a reference low power supply; and
a second resistor, a first end of the second resistor coupled to a control terminal of the first switch, and a second end of the second resistor coupled to the reference low power supply,
wherein the short circuit protection circuit receives a load voltage from the load through the first end of the second resistor, and provides the enable signal through the first end of the first switch and the diode.

13. The short circuit protection driving device of claim 12, wherein the short circuit protection circuit further comprises:
a second switch, a first end of the second switch configured to receive the power supply, and a second end of the second switch coupled to a control terminal of the first switch and the first end of the second resistor, a control terminal of the second switch coupled to the second end of the first resistor.

14. The driving device of claim 1, wherein:
the short circuit protection circuit is further configured to detect a load voltage from the load, and determines whether the load is short-circuited or not according to a voltage value of the load voltage,
when the short circuit protection circuit determines that the load is short-circuited, the enable signal is provided to stop driving the load.

15. The drive device of claim 14, wherein:
the delay circuit is further configured to determine whether a continuing time length of the load being short-circuited is greater than the delay time length,
when the delay circuit determines that the continuing time length is greater than the delay time length, the short circuit protection circuit is instructed to provide the enable signal for stopping driving the load.

16. The drive device of claim 14, further comprising:
a signal format converter, configured to convert the load voltage in the form of analog signal into the load voltage in the form of digital signal, and provide the load voltage in the form of digital signal to the short circuit protection circuit.

17. The driving device of claim 1, wherein the load has a heat-shrinkable film that shrinks when encountering thermal energy to generate a structural change of the load, and the delay time length is associated with a rate of the structural change.

18. The driving device of claim 1, wherein the load comprises at least one of an organic light-emitting diode, an organic solar cell, and an organic field-effect transistor.

19. An organic semiconductor device, comprising:
a load; and
the driving device according to claim 1 for driving the load.

20. A driving method for driving a load, the driving method comprising:
providing a delay time length according to an energy passing through the load; and
determining a start time point for providing an enable signal according to the delay time length.

21. The driving method of claim 20, further comprising:
receiving a power supply; and
providing the delayed power supply according to the delay time length.

22. The driving method of claim 21, wherein the step of determining the start time point for providing the enable signal according to the delay time length comprises:
providing a driving voltage or a driving current according to the delayed power supply delay.

23. The driving method of claim 21, wherein the step of determining the start time point for providing the enabling signal according to the delay time length comprises:
providing the start time point according to the delayed power supply.

24. The driving method of claim 20, wherein the step of determining the start time point for providing the enabling signal according to the delay time length comprises:
detecting a load voltage from the load;
determining whether the load is short-circuited according to a voltage value of the load voltage; and
when it is determined that the load is short-circuited, providing the enable signal to stop driving the load.

25. The driving method of claim 24, wherein the step of providing the enable signal to stop driving the load comprises:
determining whether a continuing time length of the load being short-circuited is greater than the delay time length,
when it is determined that the continuing time length is greater than the delay time length, providing the enable signal for stopping driving the load.
